(19) United States
(12) Patent Application Publication
(10) Pub. No.: US 2012/0135340 A1
(43) Pub. Date: May 31, 2012

(54) PHOTOMASK AND FORMATION METHOD THEREOF

(75) Inventor: Sung Hyun OH, Cheongju-si Chungcheongbuk-do (KR)

(73) Assignee: HYNIX SEMICONDUCTOR INC., Icheon-si (KR)

(21) Appl. No.: 13/305,874

(22) Filed: Nov. 29, 2011

(30) Foreign Application Priority Data
Nov. 30, 2010 (KR) 10-2010-0120550

(51) Int. Cl. G03F 1/24; G03F 1/00; G03F 1/72; G03F 1/74; B82Y 30/00; B82Y 40/00

(52) U.S. Cl. 430/5; 977/840; 977/755

(57) ABSTRACT

A method for forming a photomask includes detecting a defect of the photomask which has a mirror layer formed on a first surface of a substrate, and forming a recess groove on a first layer which is formed on a second surface of the substrate, wherein the coordinate of the recess groove corresponds to the coordinate of the defect.

### CROSS-REFERENCES TO RELATED APPLICATIONS

The present application claims priority under 35 U.S.C 119(a) to Korean Application No. 10-2010-0120550, filed on Nov. 30, 2010, in the Korean intellectual property Office, which is incorporated herein by reference in its entirety set forth in full.

### BACKGROUND

Exemplary embodiments of the present invention relate generally to a photomask, and more particularly, to a blank mask and a formation method thereof.

A photomask with mask patterns formed on a transparent substrate allows light to pass through the photomask, and the light shines onto a wafer so that desired patterns are formed on the wafer. In an exposure process applied to lithography process of semiconductor device fabrication, an electron beam may be used. However, there is a limitation in forming the mask patterns for highly integrated semiconductor devices. Among methods for overcoming such a limitation, an extreme ultraviolet lithography (EUVL) process using extreme ultraviolet (EUV) as a light source, which has a wavelength shorter than that of KrF or ArF, may be used. However, the extreme ultraviolet may be absorbed in a material of the mask pattern. In this regard, a research into an exposure method using light reflection is being conducted.

A photomask may include a mirror layer with a multilayer structure of Mo/Si layers on a substrate having a low thermal expansion coefficient (LTE) such as a quartz. Further, a light absorption pattern for partially absorbing the light is formed on the mirror layer. According to an example, the light absorption pattern is formed along the layout of patterns to be transferred onto the wafer. If a defect exists in the mirror layer with the multilayer structure, light may not be reflected in a defective area, and desired patterns may not be formed on the wafer. However, a known repair process of the photomask for the extreme ultraviolet lithography process proposes only a repair method of the light absorption pattern, and does not propose a method for repairing the mirror layer.

### SUMMARY

An embodiment of the present invention relates to a blank mask for extreme ultraviolet capable of substantially preventing a defect from being transferred onto a wafer by reducing the influence of a phase defect caused by bump-type impurity formed on a substrate in the process of fabricating a photomask for extreme ultraviolet, and a formation method thereof.

In an embodiment, a method for forming a blank mask for extreme ultraviolet includes: forming a mirror layer that reflects extreme ultraviolet incident into a first surface of the substrate; forming an electrostatic induction layer that induces static electricity on a second surface of the substrate, the second surface being opposite to the first surface of the substrate; detecting a first area including a defect occurring in a process of forming the mirror layer on the first surface of the substrate; and forming a recess groove with a first depth in a second area of the electrostatic induction layer corresponding to the detected first area, a step difference being formed between the recess groove and a surface of the second area.

In an embodiment, the mirror layer may be formed in a multilayer structure in which 30 to 60 of molybdenum layers and silicon layers are alternately deposited and the electrostatic induction layer may include chromium nitride and may be formed in a thickness of 30 nm to 60 nm.

The detecting of the first area including the defect may include: disposing a defect detection device on the substrate on which the mirror layer is formed; and checking a position, a height and a width of a defect on the substrate while moving the defect detection device in one direction.

The defect detection device may detect the defect on the substrate by irradiating actinic ray including ultraviolet onto the substrate, or using an optical method.

The defect may include one or more bump-type impurities.

The forming of the recess groove may include: forming a resist film on the electrostatic induction layer; performing an exposure and development process with respect to the resist film to form an open area that selectively exposes the electrostatic induction layer of the second area; and etching an exposed portion of the electrostatic induction layer to form the recess groove.

The recess groove may have a width which is substantially equal to or larger than a width of the defect occurring in a process of forming the mirror layer, and the recess groove may have a depth which is substantially equal to or larger than a height of the defect to induce an effect as if the height of the defect is 0 nm, so that a phase of reflected light reflected after extreme ultraviolet is incident into the first area is substantially prevented from protruding.

The recess groove may be formed by selectively irradiating an ion beam or an electron beam onto the second area of the electrostatic induction layer from focus ion beam equipment or electron beam equipment.

In an embodiment, a blank mask for extreme ultraviolet includes: a substrate; a mirror layer that reflects extreme ultraviolet incident into a first surface of the substrate; an electrostatic induction layer that induces static electricity on a second surface of the substrate, the second surface being opposite to the first surface of the substrate; and a recess groove formed in a second position of the electrostatic induction layer corresponding to a first position of a defect on the mirror layer, a step difference being formed between the recess groove and a surface of the second position.

### BRIEF DESCRIPTION OF THE DRAWINGS

The above and other aspects, features and other advantages will be more clearly understood from the following detailed description taken in conjunction with the accompanying drawings, in which:

FIG. 1 is a diagram illustrating a mask;

FIGS. 2 and 3 are diagrams explaining the influence of bump-type impurity illustrated in FIG. 1; and

FIGS. 4 to 7 are diagrams illustrating a method for forming a blank mask, which has a reduced phase error, according to an embodiment.

### DESCRIPTION OF SPECIFIC EMBODIMENTS

Hereinafter, an embodiment of the present invention will be described with reference to accompanying drawings. However, the embodiments are for illustrative purposes only and are not intended to limit the scope of the invention.

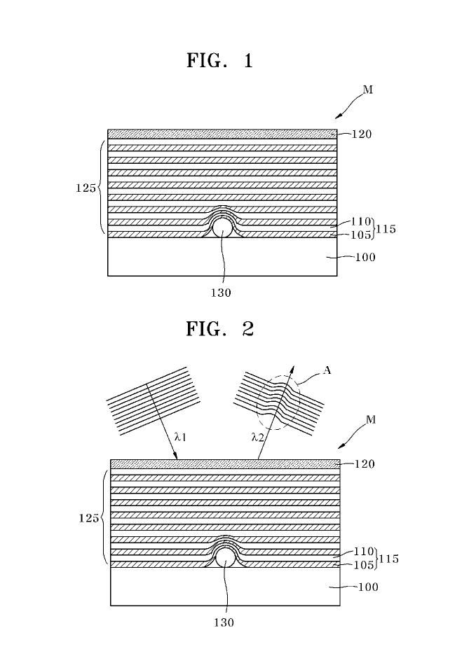

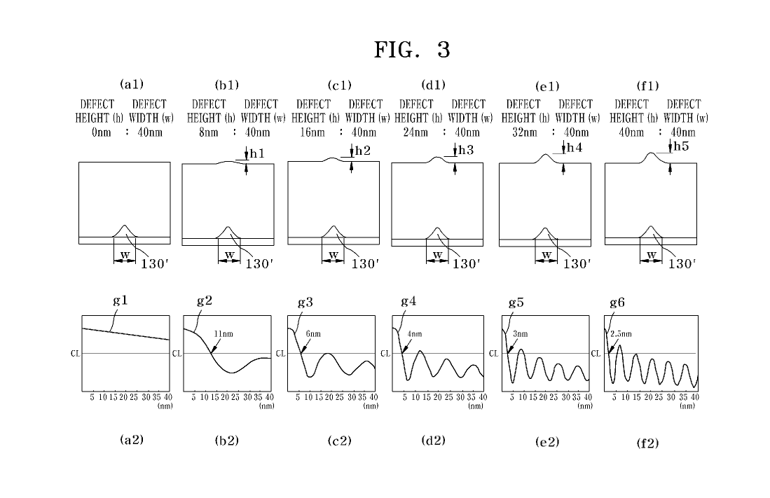

FIG. 1 is a diagram illustrating a mask. It may be a blank mask, e.g., a blank mask for extreme ultraviolet. FIGS. 2 and 3 are diagrams explaining the influence of bump-type impurity illustrated in FIG. 1.

Referring to FIGS. 1 and 2, a mirror layer 125 and a capping layer 120 are formed on a substrate 100 to form a photomask, e.g., a blank mask M for extreme ultraviolet. Since the substrate 100 may absorb energy in the process of fabricating a mask, a material with a low thermal expansion coefficient may be used for minimizing expansion and contraction of mask patterns to be formed later. Also, the substrate 100 may include an opaque material. In an embodiment, a substrate including quartz may be used.

The mirror layer 125 formed on the substrate 100 reflects light irradiated onto the mask in an exposure process. According to an example, the mirror layer 125 is formed by stacking a dual layer 115 in a multilayer configuration. Here, the dual layer 115 may include a scattering layer 105 for scattering incident extreme ultraviolet (EUV) and a spacing layer 110 for spacing scattering layers 105 from each other. The scattering layer 105 may include a molybdenum Mo layer and the spacing layer 110 may include a silicon Si layer. Further, the scattering layer 105 and the spacing layer 110 may be formed in a multilayer structure in which, according to an example, 30 layers to 60 layers are alternately deposited in order to achieve a high reflection rate. The capping layer 120 may be formed on the mirror layer 125 to reduce oxidization or contamination of the mirror layer 125. The capping layer 120 may include a chromium nitride CrN layer or ruthenium Ru layer.

In the process of forming the blank mask, one or more bump-type impurities 130 may be formed on the substrate 100 or in the mirror layer 125. The bump-type impurity 130 may be defined as particles remaining without being removed in the step of performing the deposition process for forming the scattering layer 105 and the spacing layer 110. If light, e.g., extreme ultraviolet is irradiated onto the blank mask M where the bump-type impurity 130 remains, phase difference occurs between the phases of incident extreme ultraviolet λ₁ and reflected light λ₂ reflected from an area A of the mirror layer 125 corresponding to an area where the bump-type impurity 130 exists, as illustrated in FIG. 2. Therefore, if the bump-type impurity is not removed, a phase defect with a large phase error may occur even if reflectivity difference is not large, which may have an adverse influence on wafer printability. That is, there may occur a defect that the shape of the bump-type impurity as well as the shape of a target pattern is printed on the wafer.

Referring to FIG. 3 illustrating the influence of the bump-type impurity with respect to wafer printability, it is possible to derive a result regarding whether a defect is printed on a wafer according to the heights by which the phase of reflected light reflected from a substrate or a mirror layer protrudes. In detail, (a1), (b1), (c1), (d1), (e1) and (f1) of FIG. 3 are diagrams illustrating results obtained by simulating the heights by which the phase of the reflected light reflected from the mirror layer protrudes according to the height of a defect 130′, and (a2), (b2), (c2), (d2), (e2) and (f2) of FIG. 3 are graphs g1 to g6 illustrating the defect positions on the wafer when the phase of the reflected light has the heights illustrated in (a1), (b1), (c1), (d1), (e1) and (f1) of FIG. 3. Here, the defect has the same width w of 40 nm. For example, when the defect on the mirror layer has a height of 0 nm as illustrated in (a1) of FIG. 3, since the graph g1 is above a critical line CL at which a defect occurs on the wafer as illustrated in (a2) of FIG. 3, no defect occurs on the wafer. However, referring to (b1) and (b2) of FIG. 3, when the defect on the mirror layer has a height h1 of 8 nm, since the graph g2 is below the critical line CL, the defect is printed on the wafer at an interval of 11 nm. Referring to (c1) and (c2) of FIG. 3, when the defect on the mirror layer has a height h2 of 16 nm, since the print interval of the defect on the wafer is 6 nm in the graph g3, it can be understood that the print interval of the defect is smaller than that when the defect has a height of 8 nm. This can also be understood that the defect has a larger influence on the wafer. Similarly, when the defect on the wafer has heights h3 to h5 of 24 nm, 32 nm and 40 nm (refer to (d1), (e1) and (f1) of FIG. 3), it can be understood that the print interval of the defect is reduced to 4 nm, 3 nm and 2.5 nm (refer to (d2), (e2) and (f2) of FIG. 3).

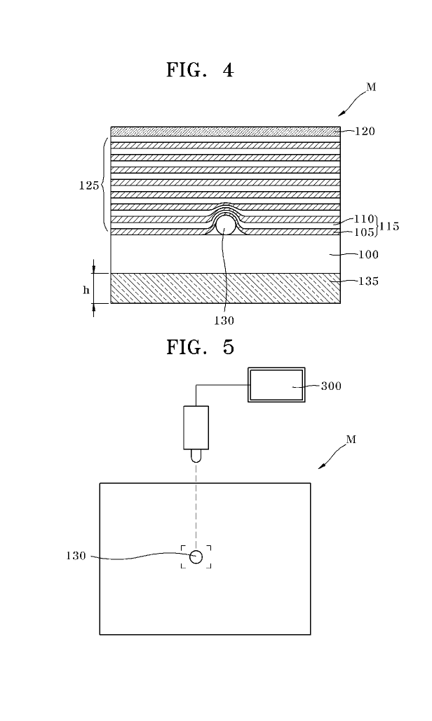

As mentioned above, as the height of the defect increases, the probability that the defect is printed on the wafer increases. In this regard, if the height of the defect is allowed to be reflected in the blank mask for extreme ultraviolet and the phase of the reflected light reflected from the mirror layer is substantially prevented from protruding, the probability that the shape of the bump-type impurity is printed on the wafer may decrease. In an embodiment, the phase change of the reflected light, reflected from the mirror layer, due to the bump-type impurity 130 may decrease by reflecting the height of the defect. This will be described with reference to FIGS. 4 to 7.

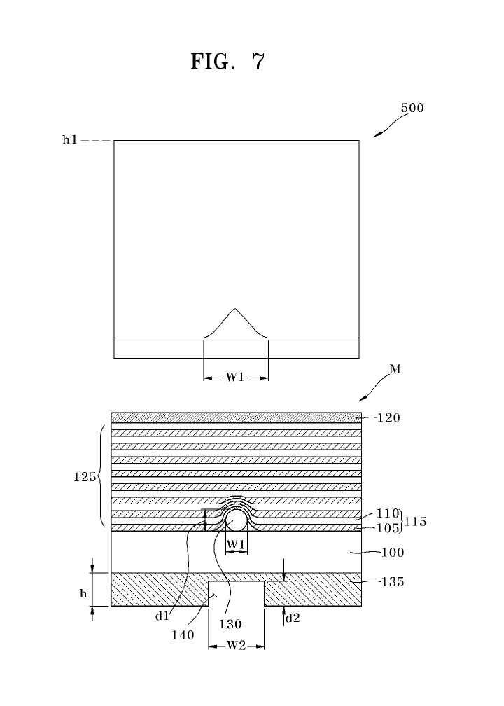

FIGS. 4 to 6 are diagrams illustrating a method for forming a photomask, e.g., a blank mask for extreme ultraviolet, which has a reduced phase error, according to an embodiment. FIG. 7 is a diagram illustrating the photomask, e.g., the blank mask for extreme ultraviolet, which has the reduced phase error, according to an embodiment.

Referring to FIG. 4, a photomask M, e.g., a blank mask for extreme ultraviolet is prepared in which a mirror layer 125 and a capping layer 120 are formed on the first surface of the substrate 100. According to an example, the mirror layer 125 formed on a substrate 100 is formed by stacking a dual layer 115 in a multilayer configuration. Here, the dual layer 115 may include a scattering layer 105 for scattering incident extreme ultraviolet (EUV) and a spacing layer 110 for spacing the scattering layers 105 from each other. The scattering layer 105 may include a molybdenum Mo layer and the spacing layer 110 may include a silicon Si layer. The scattering layer 105 and the spacing layer 110 may be formed in a multilayer structure in which, according to an example, 30 layers to 60 layers are alternately deposited. The capping layer 120 may be formed on the mirror layer 125 as a protective layer of the mirror layer 125.

An electrostatic induction layer 135 is formed on the second surface of the substrate 100, which is opposite to the first surface of the substrate 100. The first surface of the substrate 100 is a front portion of the substrate 100 and the second surface of the substrate 100 is a rear portion of the substrate 100. In a lithography process, an exposure process is performed in the state in which the substrate 100 is clamped by an electrostatic chuck (ESC) when mask patterns are formed. The electrostatic chuck is used, instead of a mechanical clamping fixture, in order to substantially prevent impurities such as particles from being transferred to the surface of a mask in an operation for physically clamping or declamping, which requires a vacuum state. In order to clamp the electrostatic chuck on the substrate 100, the electrostatic induction layer 135 for inducing electrostatic interaction between the substrate 100 and the electrostatic chuck is formed on the second surface of the substrate 100. Also, if a voltage is applied to an electrode (not illustrated) coupled to the electrostatic chuck, static electricity is generated between the electrostatic induction layer 135 and the electrode, the electrostatic induction layer 135 is clamped by the static electricity, and thus the mask for extreme ultraviolet can be clamped by the electrostatic chuck. The electrostatic induction layer 135 may include chromium nitride CrN. According to an example, the electrostatic induction layer 135 is formed in a thickness h of 30 nm to 60 nm.

Referring to FIG. 5, the position of the bump-type impurity 130 generated on the substrate 100 or in the mirror layer 125 is detected. In detail, a defect detection device 300 is disposed on the substrate 100 on which the mirror layer 125 is formed. The defect detection device 300 detects a defect by irradiating actinic ray including ultraviolet onto the substrate 100, or using an optical method. The coordinate of the bump-type impurity 130 on the substrate 100 is checked while moving the defect detection device 300 in a certain direction. Thus, it is possible to check the height and width of the bump-type impurity 130 detected by the coordinate using the defect detection device 300.

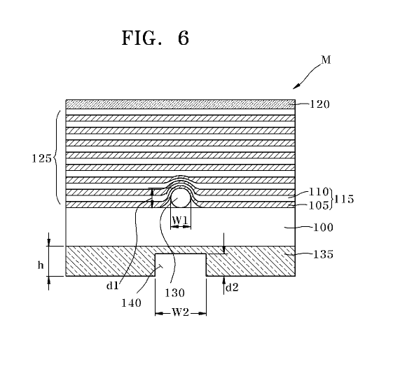

Referring to FIG. 6, a partial area of the electrostatic induction layer 135 is etched to form a recess groove 140. In detail, a part of the electrostatic induction layer 135 corresponding to the position of the bump-type impurity 130 checked using the defect detection device 300 (refer to FIG. 5) is etched to form the recess groove 140 in the electrostatic induction layer 135. The recess groove 140 formed in the electrostatic induction layer 135 may have a second width w2 which is substantially equal to or larger than the first width w1 of the bump-type impurity 130, and have a first depth d2 larger than a height d1 of the bump-type impurity 130. The recess groove 140 may be formed such that the electrostatic induction layer 135 has a thickness enough for generating static electricity when the mask is clamped by the electrostatic chuck later.

The recess groove 140 in the electrostatic induction layer 135 may be formed using an etch process, or by irradiating a laser beam. For example, a photo resist film (not illustrated) is formed on the electrostatic induction layer 135, and an exposure and development process is performed with respect to the photo resist film to form an open area for selectively exposing a portion of the electrostatic induction layer, which corresponds to the position where a defect has occurred. The electrostatic induction layer 135 exposed by the open area is etched to form the recess groove 140 with the second width w2 and the first depth d2 in the electrostatic induction layer 135. The recess groove 140 in the electrostatic induction layer 135 may be formed by selectively irradiating an ion beam or an electron beam onto the electrostatic induction layer 135 from focus ion beam equipment or electron beam equipment.

Referring to FIG. 7 illustrating the phase 500 of the reflected light reflected after extreme ultraviolet is incident into the blank mask M for extreme ultraviolet formed as illustrated in FIGS. 4 to 6, an effect as if the height of the bump-type impurity h1 is 0 nm is induced by the recess groove 140 having the first depth d2 larger than the height d1 of the bump-type impurity 130. Therefore, the probability of the phase change of the reflected light may decrease.

According to the invention, when the bump-type impurity is generated to induce a phase error on the mirror layer of the photomask, e.g., the blank mask for extreme ultraviolet, the position of the bump-type impurity is checked and a phase error of an area where the bump-type impurity is positioned is reduced, so that desired patterns can be formed on the wafer.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method for forming a photomask, comprising:
detecting a defect of the photomask which has a mirror layer formed on a first surface of a substrate; and
forming a recess groove on a first layer which is formed on a second surface of the substrate, wherein the coordinate of the recess groove corresponds to the coordinate of the defect.

2. The method of claim 1, wherein the first layer includes an electrostatic induction layer.

3. The method of claim 1, wherein the mirror layer is formed in a multilayer structure in which 30 to 60 of molybdenum layers and silicon layers are alternately deposited.

4. The method of claim 2, wherein the electrostatic induction layer includes chromium nitride and is formed in a thickness of 30 nm to 60 nm.

5. The method of claim 1, wherein the detecting of the defect comprises:
disposing a defect detection device on the substrate on which the mirror layer is formed; and
checking a position, a height and a width of a defect over the substrate while moving the defect detection device in a direction.

6. The method of claim 5, wherein the defect detection device detects the defect on the substrate by irradiating actinic ray including ultraviolet onto the substrate, or using an optical method.

7. The method of claim 1, wherein the defect includes a bump-type impurity.

8. The method of claim 1, wherein the forming of the recess groove comprises:
forming a photo resist film on the first layer;
performing an exposure and development process with respect to the resist film to form an open area that selectively exposes the first layer; and
etching an exposed portion of the first layer to form the recess groove.

9. The method of claim 1, wherein the recess groove has a width which is substantially equal to or larger than a width of the defect.

10. The method of claim 1, wherein the recess groove has a depth which is substantially equal to or larger than a height of the defect.

11. The method of claim 1, wherein the recess groove is formed by selectively irradiating an ion beam or an electron beam onto a portion of the electrostatic induction layer from focus ion beam equipment or electron beam equipment.

12. A photomask comprising:
a substrate;
a mirror layer that reflects light incident into a first surface of the substrate;
a first layer formed on a second surface of the substrate, wherein the second surface of the substrate is opposite to the first surface of the substrate; and
a recess groove formed on the first layer, wherein the coordinate of the recess groove corresponds to the coordinate of a defect formed over substrate.

13. The photomask of claim 12, wherein the first layer includes an electrostatic induction layer.

14. The photomask of claim 12, wherein the photomask includes a blank mask for extreme ultraviolet.

15. The photomask of claim 12, wherein the mirror layer is formed in a multilayer structure in which 30 to 60 of molybdenum layers and silicon layers are alternately deposited.

16. The photomask of claim 13, wherein the electrostatic induction layer includes chromium nitride and is formed in a thickness of 30 nm to 60 nm.

17. The photomask of claim 12, wherein the recess groove has a width which is substantially equal to or larger than a width of the defect.

18. The photomask of claim 12, wherein the recess groove has a depth which is substantially equal to or larger than a height of the defect.
